(19) United States
(12) Patent Application Publication
(10) Pub. No.: US 2015/0256127 A1
(43) Pub. Date: Sep. 10, 2015

(54) ELECTRONIC DEVICE, ELECTRONIC APPARATUS AND MOVING OBJECT

(71) Applicant: Seiko Epson Corporation, Tokyo (JP)

(72) Inventors: Yuichi TAKEBAYASHI, Minowa (JP); Yoshiaki MATSUMOTO, Ina (JP)

(21) Appl. No.: 14/640,319

(22) Filed: Mar. 6, 2015

(30) Foreign Application Priority Data
Mar. 10, 2014 (JP) 2014-046979

(51) Int. Cl. H03B 1/02; H03B 5/32

(52) U.S. Cl. CPC H03B 1/02; H03B 5/326

(57) ABSTRACT

An electronic device includes a base material provided with a concave portion and a support substrate provided with lateral sides. The support substrate is located so as to overlap the concave portion when seen in plan view, and is bonded to an upper surface of the base material through solders at a plurality of places except both ends of the lateral side and a plurality of places except both ends of the lateral side.

### BACKGROUND

1. Technical Field

The present invention relates to an electronic device, an electronic apparatus and a moving object.

2. Related Art

Hitherto, oscillators using a SAW (Surface Acoustic Wave) resonator or a quartz crystal resonator have been known, and widely used as a reference frequency source, an oscillation source, or the like of various electronic apparatuses.

An electronic device disclosed in JP-A-2005-167508 includes a package constituted by a mounting substrate and a metal case, a printed substrate, disposed within the package, which is fixed to the mounting substrate, and a quartz crystal resonator and an IC component which are mounted in the printed substrate. Such a configuration is considered to be effective in that the printed substrate serves as a reinforcement member that reinforces the mechanical strength of the package, thereby allowing the mechanical strength of the package to be increased. However, in the electronic device disclosed in JP-A-2005-167508, since the entire circumferential portion of the printed substrate is fixed to the mounting substrate, excessive stress is applied to the printed substrate, the mounting substrate, and the bonding portion therebetween due to stress or the like which is generated by a thermal expansion difference between the mounting substrate and the printed substrate, which results in a concern of the printed substrate or the mounting substrate being damaged.

In addition, an electronic device disclosed in JP-A-2000-174204 includes a package constituted by a first dielectric substrate and a metal cover, a second dielectric substrate, disposed within the package, which is fixed to a metal base, and an RF semiconductor device which is mounted in the second dielectric substrate. However, even in such an electronic device disclosed in JP-A-2000-174204, since the entire circumferential portion of the second dielectric substrate is fixed to the first dielectric substrate, there may be a concern of the occurrence of the same problem as in the electronic device disclosed in JP-A-2005-167508 described above.

### SUMMARY

An advantage of some aspects of the invention is to provide an electronic device, an electronic apparatus and a moving object which are capable of reducing damage due to stress which is likely to be generated by thermal expansion while increasing the mechanical strength of a package.

The invention can be implemented as the following forms or application examples.

### APPLICATION EXAMPLE 1

This application example is directed to an electronic device including a base material in which a concave portion is provided, and a substrate that includes a lateral side to which a first main surface and a second main surface, being in a front-back relationship with each other, are connected, the lateral side including a first lateral side and a second lateral side which are disposed so as to face each other, and a third lateral side and a fourth lateral side, disposed so as to face each other, which intersect the first lateral side and the second lateral side. The substrate overlaps an opening region of the concave portion when seen in plan view, and the second main surface faces the inner bottom of the concave portion. At least any one of at least a portion of a region between both ends of the first lateral side in a direction in which the third lateral side and the fourth lateral side are linked, and at least a portion of a region between both ends of the second lateral side in the linking direction is bonded to a sidewall of the concave portion through a connecting member.

With this configuration, the substrate functions as a reinforcement member of the base material, and thus it is possible to increase the mechanical strength of the package. In addition, since the substrate is bonded to the base material on at least one of the first lateral side and the second lateral side, it is possible to obtain an electronic device which is capable of reducing stress which is likely to be generated in the substrate due to thermal expansion.

### APPLICATION EXAMPLE 2

In the electronic device according to this application example, it is preferable that the substrate is formed of ceramic.

With this configuration, since the mechanical strength of the substrate becomes relatively high, the substrate functions as a reinforcement member of the base material, and thus it is possible to further increase the mechanical strength of the package.

### APPLICATION EXAMPLE 3

In the electronic device according to this application example, it is preferable that an external connection terminal is provided on a surface of the concave portion on an opposite side to the inner bottom, and that when seen in plan view, a maximum value of a distance between a connection place of the substrate with the base material and a center of the base material is smaller than a maximum value of a distance between a portion of the external connection terminal contacting an outer edge of the surface on the opposite side and the center of the base material.

With this configuration, it is possible to reduce the generation of cracks in the connecting member that connects the substrate to the base material.

### APPLICATION EXAMPLES 4 AND 5

In the electronic device according to this application example, it is preferable that a lid which is bonded to the base material so as to cover the substrate is further included, and that the lid is bonded to a portion of the sidewall located along the third lateral side and a portion of the sidewall located along the fourth lateral side.

With this configuration, the lid functions as a reinforcement member of the base material, and thus an electronic device is obtained which is capable of reducing stress which is likely to be generated in the substrate due to thermal expansion while further increasing the mechanical strength of the package.

### APPLICATION EXAMPLE 6

In the electronic device according to this application example, it is preferable that a columnar member is provided between the first main surface and the lid, and that the columnar member comes into contact with the substrate and the lid.

With this configuration, it is possible to reduce the bending of the lid, and to further increase the mechanical strength of the electronic device.

### APPLICATION EXAMPLE 7

In the electronic device according to this application example, it is preferable that a first electronic part, provided on the first main surface, which serves as the columnar member is further included.

With this configuration, the first electronic part is used as the columnar member, and thus a member having a function of only the columnar member is not required to be disposed, thereby allowing a reduction in the size of the electronic device to be achieved.

### APPLICATION EXAMPLE 8

In the electronic device according to this application example, it is preferable that a resonator and a circuit which is connected to the resonator are provided on the substrate, and that the first electronic part is a circuit element included in the resonator or the circuit.

With this configuration, the resonator or the circuit element which is a relatively tall electronic part is used as the columnar member, and thus a member having a function of only the columnar member is not required to be disposed, thereby allowing a reduction in the size of the electronic device to be achieved.

### APPLICATION EXAMPLE 9

In the electronic device according to this application example, it is preferable that a second electronic part, provided on the second main surface, which comes into contact with the bottom plate is further included.

With this configuration, it is possible to reduce the bending of the bottom plate, and to further increase the mechanical strength of the electronic device.

### APPLICATION EXAMPLE 10

In the electronic device according to this application example, it is preferable that a second electronic part, provided on the second main surface, which is connected to the bottom plate through a connecting member is further included.

With this configuration, it is possible to reduce the bending of the bottom plate, and to further increase the mechanical strength of the electronic device. In addition, in some cases, it is also possible to achieve electrical connection between the second electronic part and the base material.

### APPLICATION EXAMPLE 11

In the electronic device according to this application example, it is preferable that a resonator and a circuit which is connected to the resonator are provided on the substrate, and that the second electronic part is a circuit element included in the resonator or the circuit.

With this configuration, it is possible to effectively use the resonator or the circuit element which is a relatively tall electronic part, as an electronic part for reducing the bending of the bottom plate.

### APPLICATION EXAMPLES 12, 13, AND 14

These application examples are directed to an electronic apparatus including the electronic device according to the application example described above.

With this configuration, it is possible to obtain an electronic apparatus having high reliability.

### APPLICATION EXAMPLES 15, 16, AND 17

These application examples are directed to a moving object including the electronic device according to the application example described above.

With this configuration, it is possible to obtain a moving object having high reliability.

### BRIEF DESCRIPTION OF THE DRAWINGS

The invention will be described with reference to the accompanying drawings, wherein like numbers reference like elements.

FIG. 1 is a perspective view illustrating an electronic device according to a first embodiment of the invention.

FIG. 2 is a cross-sectional view illustrating the electronic device shown in FIG. 1.

FIGS. 3A and 3B are plan views illustrating a base material included in the electronic device shown in FIG. 1; FIG. 3A is a top view, and FIG. 3B is a see-through view when seen from the upper side.

FIG. 4 is a cross-sectional view illustrating the electronic device shown in FIG. 1.

FIG. 5 is a perspective view illustrating a state where a lid of the electronic device shown in FIG. 1 is removed.

FIG. 6 is a plan view illustrating a support substrate included in the electronic device shown in FIG. 1.

FIG. 7 is a block diagram illustrating a circuit included in the electronic device shown in FIG. 1.

FIGS. 8A and 8B are a cross-sectional view and a plan view, respectively, illustrating a SAW resonator included in the electronic device shown in FIG. 1.

FIG. 9 is a cross-sectional view illustrating an electronic device according to a second embodiment of the invention.

FIG. 10 is a cross-sectional view illustrating an electronic device according to a third embodiment of the invention.

FIG. 11 is a plan view illustrating an electronic device according to a fourth embodiment of the invention.

FIG. 12 is a cross-sectional view illustrating an electronic device according to a fifth embodiment of the invention.

FIG. 13 is a cross-sectional view illustrating an electronic device according to a sixth embodiment of the invention.

FIG. 14 is a cross-sectional view illustrating an electronic device according to a seventh embodiment of the invention.

FIG. 15 is a perspective view illustrating a configuration a mobile-type (or note-type) personal computer to which an electronic apparatus according to the invention is applied.

FIG. 16 is a perspective view illustrating a configuration of a cellular phone (also including PHS) to which an electronic apparatus according to the invention is applied.

FIG. 17 is a perspective view illustrating a configuration of a digital still camera to which an electronic apparatus according to the invention is applied.

FIG. 18 is a perspective view illustrating an automobile to which a moving object according to the invention is applied.

### DESCRIPTION OF EXEMPLARY EMBODIMENTS

Hereinafter, an electronic apparatus, an electronic device and a moving object according to the invention will be described in detail on the basis of embodiments shown in the accompanying drawings.

### 1. Electronic Device

### First Embodiment

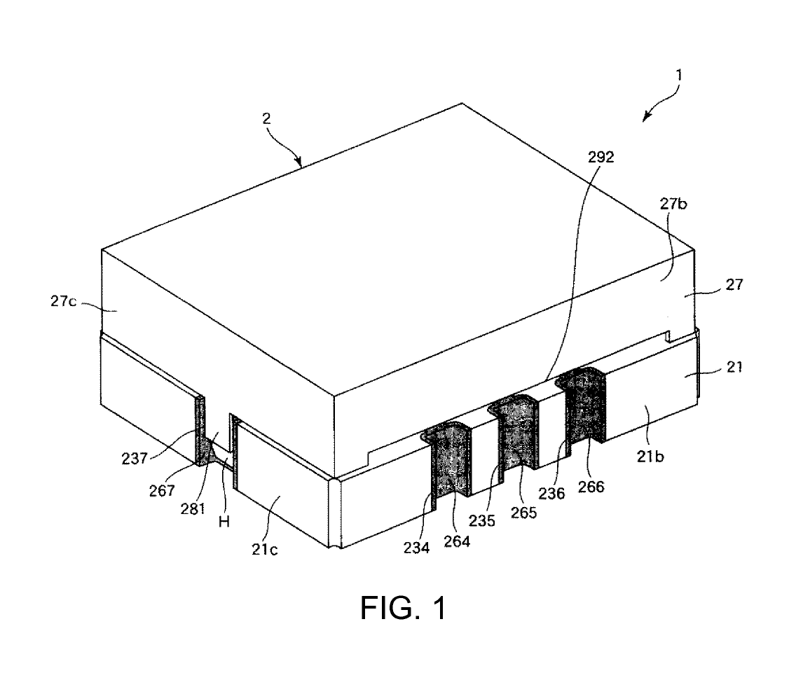

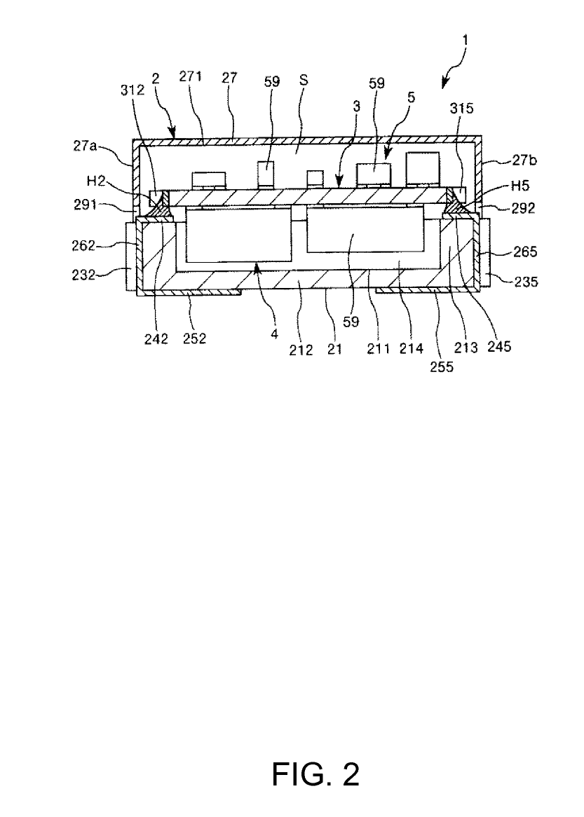

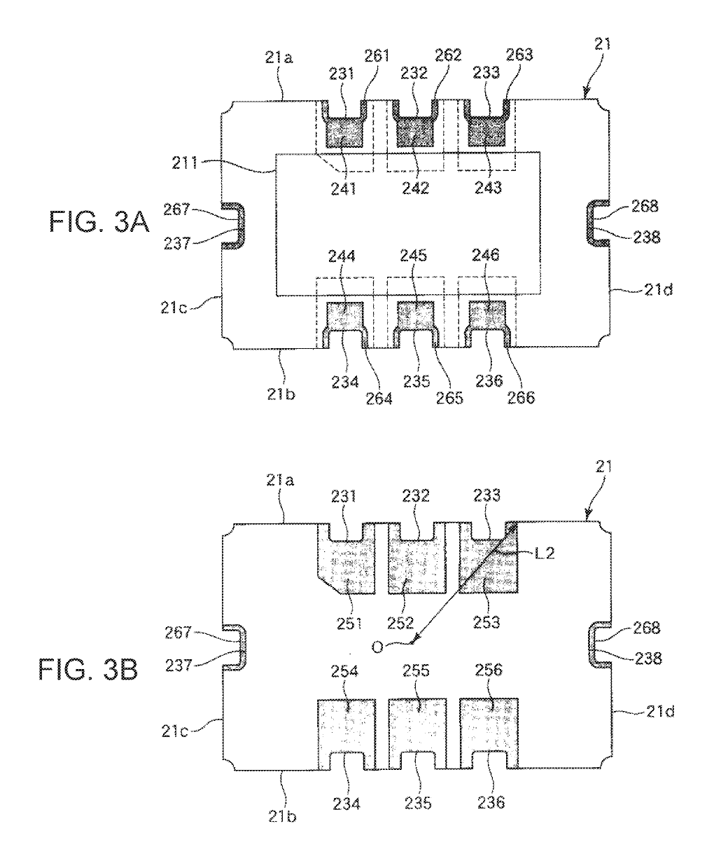

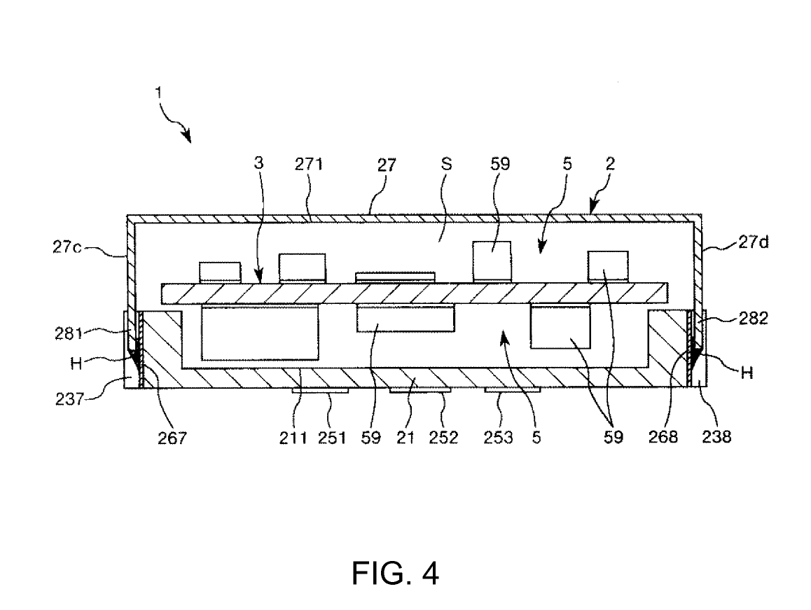

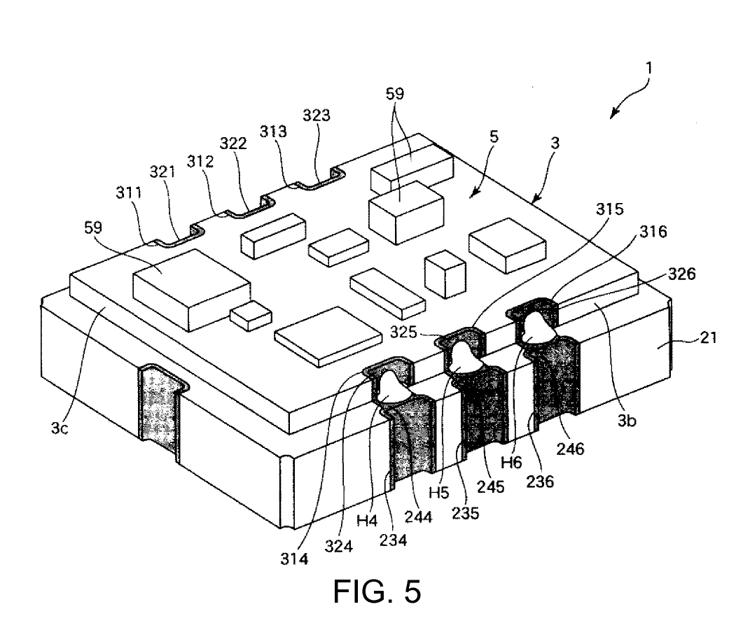

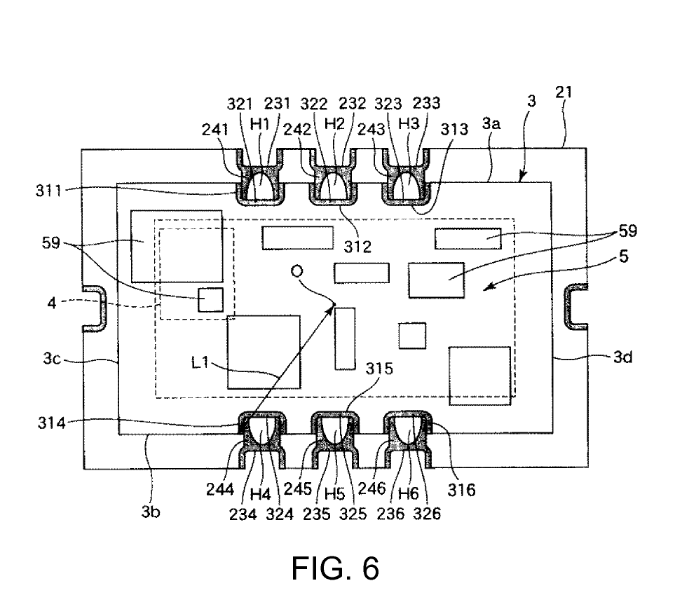

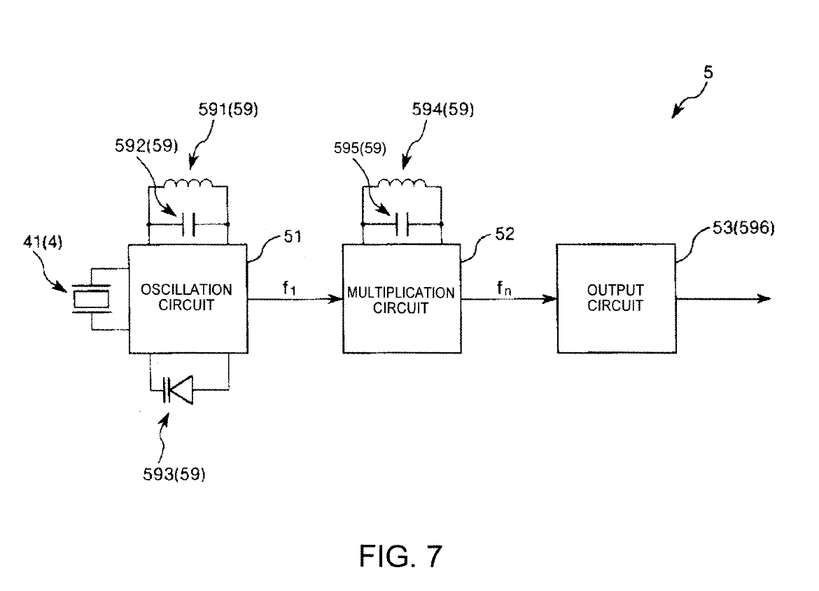

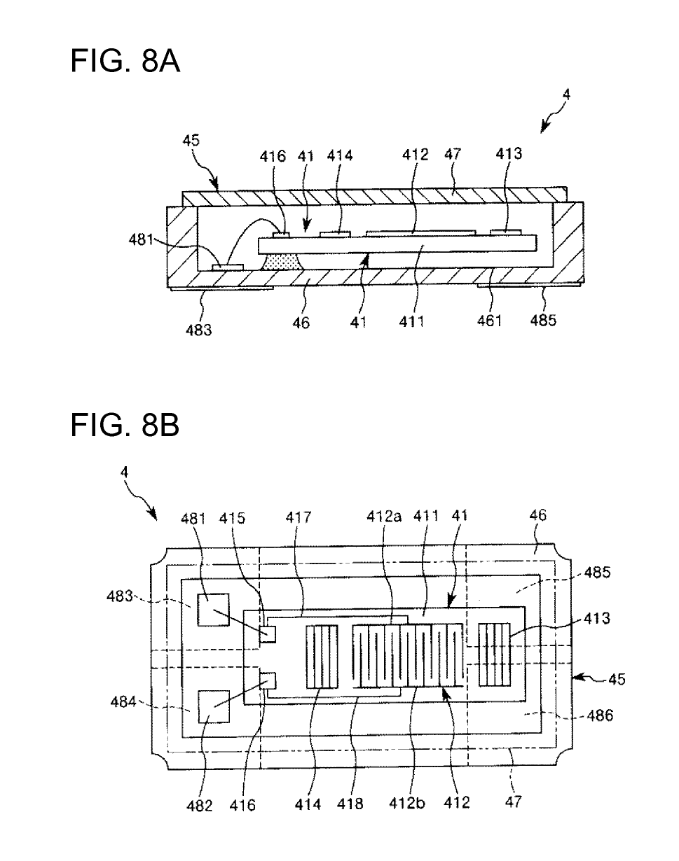

FIG. 1 is a perspective view illustrating an electronic device according to a first embodiment of the invention. FIG. 2 is a cross-sectional view illustrating the electronic device shown in FIG. 1. FIGS. 3A and 3B are plan views illustrating a base material included in the electronic device shown in FIG. 1; FIG. 3A is a top view, and FIG. 3B is a see-through view when seen from the upper side. FIG. 4 is a cross-sectional view illustrating the electronic device shown in FIG. 1. FIG. 5 is a perspective view illustrating a state where a lid of the electronic device shown in FIG. 1 is removed. FIG. 6 is a plan view illustrating a support substrate included in the electronic device shown in FIG. 1. FIG. 7 is a block diagram illustrating a circuit included in the electronic device shown in FIG. 1. FIGS. 8A and 8B are a cross-sectional view and a plan view, respectively, illustrating a SAW resonator included in the electronic device shown in FIG. 1. Meanwhile, hereinafter, for convenience of description, an upper side in FIG. 2 is defined as “upper”, and a lower side is defined as “lower”.

An electronic device 1 shown in FIG. 1 includes a package 2, a support substrate (substrate) 3 which is fixed into the package 2, and a SAW resonator (vibrator) 4 and a circuit 5 which are mounted onto the support substrate 3, and is an electronic device constituting a voltage controlled SAW oscillator (VCSO). Hereinafter, each of these components will be sequentially described.

### Package

As shown in FIGS. 1 and 2, the package 2 includes a base material 21 and a lid 27 which is bonded to the base material 21. An internal space S is provided between the base material 21 and the lid 27 within the package 2, and the support substrate 3, the SAW resonator 4 and the circuit 5 are stored and disposed in this internal space S.

As shown in FIGS. 3A and 3B, the base material 21 is formed in a box shape having a concave portion 211 which is open to the upper surface. In other words, the base material includes a plate-like bottom plate 212, a frame-like sidewall 213 which is disposed upright from the marginal portion of the upper surface of the bottom plate 212, and a region 214 which is surrounded by the sidewall 213. In addition, the base material 21 is formed in an approximately rectangular shape when seen in plan view, and includes a pair of lateral sides 21a and 21b extending in a long-axis direction and a pair of lateral sides 21c and 21d extending in a short-axis direction.

In addition, three notched portions 231, 232, and 233 extending from the upper surface to the lower surface are provided side by side on the lateral side 21a, and these notched portions 231, 232, and 233 are disposed near the central portion so as to keep away from both ends of the lateral side 21a. Similarly to this, three notched portions 234, 235, and 236 extending from the upper surface to the lower surface are also provided side by side on the lateral side 21b, and these notched portions 234, 235, and 236 are disposed near the central portion so as to keep away from both ends of the lateral side 21b. As described later, castellations are formed in these notched portions 231 to 236.

In addition, a notched portion 237 extending from the upper surface to the lower surface is provided on the lateral side 21c, and this notched portion 237 is provided at the central portion of the lateral side 21c. Similarly to this, a notched portion 238 extending from the upper surface to the lower surface is also provided on the lateral side 21d, and this notched portion 238 is provided at the central portion of the lateral side 21d. As described later, claw portions 281 and 282 of the lid 27 are disposed in the notched portions 237 and 238, respectively.

In addition, six internal terminals 241, 242, 243, 244, 245, and 246 are provided on the upper surface of the base material 21, and six external connection terminals (user terminals) 251, 252, 253, 254, 255, and 256 are provided on the lower surface of the base material 21. For example, a power supply terminal, a GND terminal, an output terminal, and the like are included in these external connection terminals 251 to 256. In addition, castellations 261, 262, 263, 264, 265, 266, 267, and 268 are disposed in the notched portions 231, 232, 233, 234, 235, 236, 237, and 238, respectively.

Specifically, the internal terminal 241 and the external connection terminal 251 are disposed side by side in the notched portion 231, and are electrically connected to each other through the castellation 261. Similarly, the internal terminal 242 and the external connection terminal 252 are disposed side by side in the notched portion 232, and are electrically connected to each other through the castellation 262. In addition, the internal terminal 243 and the external connection terminal 253 are disposed side by side in the notched portion 233, and are electrically connected to each other through the castellation 263. In addition, the internal terminal 244 and the external connection terminal 254 are disposed side by side in the notched portion 234, and are electrically connected to each other through the castellation 264. In addition, the internal terminal 245 and the external connection terminal 255 are disposed side by side in the notched portion 235, and are electrically connected to each other through the castellation 265. In addition, the internal terminal 246 and the external connection terminal 256 are disposed side by side in the notched portion 236, and are electrically connected to each other through the castellation 266. In addition, each of the castellations 267 and 268 are electrically connected to the GND terminal included in the external connection terminals 251 to 256 through a wiring (not shown) which is formed inside the base material 21. Meanwhile, besides the aforementioned state, each of the electrical connections between the internal terminal 241 and the external connection terminal 251, between the internal terminal 242 and the external connection terminal 252, between the internal terminal 243 and the external connection terminal 253, between the internal terminal 244 and the external connection terminal 254, between the internal terminal 245 and the external connection terminal 255, and between the internal terminal 246 and the external connection terminal 256 may be made through a via conductor which is formed to pass through the base material 21, may be made through a wiring which is formed within the base material 21, and may be made by configurations having a plurality of combinations of these components and the castellations.

Such a base material 21 is obtained by laminating a plurality of substrates which are formed of a ceramic green sheet such as, for example, an aluminum oxide substance, an aluminum nitride substance, a silicon carbide substance, a mullite substance, or a glass ceramic substance, and sintering this laminated body. In addition, each of the internal terminals 241 to 246, the external connection terminals 251 to 256, and the castellations 261 to 268 is obtained by coating, for example, a plated layer of gold (Au), copper (Cu) or the like on an underlying layer of tungsten (W), molybdenum (Mo) or the like.

On the other hand, the lid 27 is formed in a box shape having a concave portion 271 which is open to the lower surface. In addition, the lid 27 has an approximately rectangular outer shape corresponding to the base material 21 when seen in plan view, and has a pair of lateral sides 27a and 27b extending in a long-axis direction and a pair of lateral sides 27c and 27d extending in a short-axis direction.

In addition, as shown in FIGS. 1 and 4, the lid 27 has the claw portions 281 and 282 protruding downward from the lateral sides 27c and 27d, and is configured such that these claw portions 281 and 282 are inserted into the notched portions 237 and 238 of the base material 21. The claw portions 281 and 282 and the castellations 267 and 268 which are disposed in the notched portions 237 and 238 are bonded by solder (metal brazing material) H, and thus the lid 27 is bonded to the base material 21. Meanwhile, in addition to the above, a conductive member (conductive bonding member) such as a conductive adhesive, silver solder, or gold solder may be used in the bonding between the claw portions 281 and 282 and the castellations 267 and 268, and the claw portions 281 and 282 and the castellations 267 and 268 may be melted by welding or the like and be bonded to each other.

In addition, as shown in FIGS. 1 and 2, concave omission portions (notched portions) 291 and 292 which are opened to the lower surface are formed on the lateral sides 27a and 27b of the lid 27, and the contact between the lid 27 and the internal terminals 241 to 246 is prevented by the omission portions 291 and 292.

Such a lid 27 is formed of a metal material. Thereby, since the lid 27 is electrically connected to the GND terminal through the solder H and the castellations 267 and 268, the lid 27 functions as a shield layer that cuts off or attenuates a signal (noise) from the outside. Therefore, the electronic device 1 having excellent oscillation characteristics and high reliability is obtained. Meanwhile, as a metal material constituting the lid 27, a material having a linear expansion coefficient approximate to that of the base material 21 may be preferably used. For example, when ceramics are used as the configuration material of the base material 21, it is preferable to use an alloy such as Kovar. In addition, the lid 27 may be formed of an insulating member which is formed of, for example, a member such as ceramic, resin or glass, or a member having these materials mixed in, and may have a configuration in which a metal is attached onto the surface of the lid by a method such as plating, evaporation, sputtering, application or printing, or a method incorporating these processes.

### Support Substrate

The support substrate 3 is formed of a low-temperature co-fired ceramic substrate (LTCC substrate). Thereby, the support substrate 3 having a high strength is obtained. In addition, it is possible to simultaneously form a wiring pattern, and to reduce the number of processes for manufacturing the electronic device 1. Meanwhile, the support substrate 3 may be a single-layered substrate, and may be a multi-layered substrate. In addition, the support substrate 3 is not limited to the low-temperature co-fired ceramic substrate. Besides, for example, a ceramic substrate other than the low-temperature co-fired ceramic substrate, a resin substrate (printed substrate) formed of glass epoxy or other configuration members, a glass substrate, or the like may be used therein.

Such a support substrate 3 is formed in a plate shape. In addition, the support substrate 3 is formed in a rectangular shape corresponding to the base material 21 when seen in plan view, and the lateral side thereof for connecting an upper surface (first main surface) and a lower surface (second main surface) has a pair of lateral sides (first and second lateral sides) 3a and 3b extending in a long-axis direction and a pair of lateral sides (third and fourth lateral sides) 3c and 3d extending in a short-axis direction.

In addition, three notched portions 311, 312, and 313 extending from the upper surface to the lower surface are provided side by side on the lateral side 3a, and these notched portions 311, 312, and 313 are disposed near the central portion so as to keep away from both ends of the lateral side 3a. Similarly to this, three notched portions 314, 315, and 316 extending from the upper surface to the lower surface are also provided side by side on the lateral side 3b, and these notched portions 314, 315, and 316 are disposed near the central portion so as to keep away from both ends of the lateral side 3b. Castellations 321, 322, 323, 324, 325, and 326 are formed in these notched portions 311, 312, 313, 314, 315, and 316, respectively.

In addition, as shown in FIG. 6, when seen in plan view, the notched portions 311 to 316 are located further inside (at the center side of the base material 21) than the notched portions 231 to 236 which are formed in the base material 21. Further, the notched portion 311 is provided so as to be lined up with the notched portion 231 and overlap the internal terminal 241. Similarly to this, the notched portion 312 is provided so as to be lined up with the notched portion 232 and overlap the internal terminal 242, the notched portion 313 is provided so as to be lined up with the notched portion 233 and overlap the internal terminal 243, the notched portion 314 is provided so as to be lined up with the notched portion 234 and overlap the internal terminal 244, the notched portion 315 is provided so as to be lined up with the notched portion 235 and overlap the internal terminal 245, and the notched portion 316 is provided so as to be lined up with the notched portion 236 and overlap the internal terminal 246.

As shown in FIGS. 5 and 6, the support substrate 3 having such a configuration is located so as to overlap the concave portion 211 (region 214) when seen in plan view, and is fixed to the upper surface (main surface of the sidewall 213) of the base material 21 by six solders (fixing members) H1 to H6. A fixing member that fixes the support substrate 3 to the base material 21 is not limited to the solder. A metal brazing material such as, for example, gold solder or silver solder, or a conductive adhesive may be used therein, and the castellations 321, 322, 323, 324, 325, and 326 and the internal terminals 241, 242, 243, 244, 245, and 246 may be melted by welding or the like and be bonded to each other.

The solder H1 is located on the internal terminal 241, and has a fillet formed in the notched portion 311. Thereby, the support substrate 3 is fixed to the base material 21, and the internal terminal 241 and the castellation 321 are electrically connected to each other. Similarly, the solder H2 is located on the internal terminal 242, and has a fillet formed in the notched portion 312. Thereby, the support substrate 3 is fixed to the base material 21, and the internal terminal 242 and the castellation 322 are electrically connected to each other. In addition, the solder H3 is located on the internal terminal 243, and has a fillet formed in the notched portion 313. Thereby, the support substrate 3 is fixed to the base material 21, and the internal terminal 243 and the castellation 323 are electrically connected to each other. In addition, the solder H4 is located on the internal terminal 244, and has a fillet formed in the notched portion 314. Thereby, the support substrate 3 is fixed to the base material 21, and the internal terminal 244 and the castellation 324 are electrically connected to each other. In addition, the solder H5 is located on the internal terminal 245, and has a fillet formed in the notched portion 315. Thereby, the support substrate 3 is fixed to the base material 21, and the internal terminal 245 and the castellation 325 are electrically connected to each other. In addition, the solder H6 is located on the internal terminal 246, and has a fillet formed in the notched portion 316. Thereby, the support substrate 3 is fixed to the base material 21, and the internal terminal 246 and the castellation 326 are electrically connected to each other.

### Circuit

As shown in FIGS. 2, 5, and 6, the circuit 5 includes a wiring pattern (not shown) which is formed on the upper surface, the lower surface and the inside of the support substrate 3, and a plurality of circuit elements 59, mounted in the support substrate 3, which are connected to each other by the wiring pattern. The wiring pattern is connected to the castellations 321 to 326. Thereby, the wiring pattern and the external connection terminals 251 to 256 are electrically connected to each other.

As shown in FIG. 7, such a circuit 5 includes an oscillation circuit 51 that oscillates the SAW resonator 4, a multiplication circuit 52 that increases an output frequency f1 from the oscillation circuit 51 n times, and an output circuit 53 that converts an output frequency fn (=f1×n) from the multiplication circuit 52 into a predetermined output format (such as CMOS, LV-PECL, or LVDS) to output the resultant. The multiplication circuit 52 includes a bandpass filter, and outputs the output frequency fn by passing the frequency fn which is superimposed on the output frequency f1 from the oscillation circuit 51 and attenuating the other frequencies ( . . . f1×(n−1), f1×(n+1) . . . ).

Each of the oscillation circuit 51 and the multiplication circuit 52 of the present embodiment is a circuit having a plurality of discrete parts lined up therein, and the output circuit 53 is an integrated circuit. Therefore, the circuit element 59 includes, for example, a chip coil (chip inductor) 591, a chip capacitor 592, a varicap (variable capacitance diode) 593 and a resistor which are included in the oscillation circuit 51, a chip coil (chip inductor) 594, a chip capacitor 595 and a resistor, included in the multiplication circuit 52, that constitute a bandpass filter, an IC chip 596 constituting the output circuit 53, and the like. The oscillation circuit 51 and the multiplication circuit 52 may also be configured as an integrated circuit similarly to the output circuit 53, and at least two circuits of the oscillation circuit 51, the multiplication circuit 52, and the output circuit 53 may be formed within one integrated circuit.

When the oscillation circuit 51 and the multiplication circuit 52 are not configured as an integrated circuit, but configured as a circuit having discrete parts lined up therein, for example, it is thus possible to exhibit the following effects. It is possible to adjust the output frequency from the oscillation circuit 51 by exchanging the chip coil 591 or the chip capacitor 592, included in the oscillation circuit 51, for an element having different inductance or capacitance, and to thereby make the output frequency f1 conform to a desired frequency. In addition, it is possible to adjust the bandpass of the bandpass filter by exchanging the chip coil 594 or the chip capacitor 595, included in the multiplication circuit 52, for an element having different inductance or capacitance, and to thereby suppress a spurious signal (unnecessary signal) by attenuating frequencies other than the output frequency fn. In this manner, the oscillation circuit 51 and the multiplication circuit 52 are not configured as an integrated circuit, but configured as a circuit having discrete parts lined up therein, and thus it is possible to easily perform various types of adjustments of the electronic device 1. Meanwhile, since the output circuit 53 has little scope to implement an adjustment function unlike the oscillation circuit 51 or the multiplication circuit 52, the output circuit being configured as an integrated circuit makes it possible to achieve a reduction in the size of the circuit 5.

Meanwhile, the circuit 5 may include, for example, a temperature compensation circuit, in addition to these circuits 51, 52, and 53. In addition, when a frequency to be output from the electronic device 1 can be output from the oscillation circuit 51, the multiplication circuit 52 may be omitted. In addition, the circuit 5 includes the SAW resonator 4 for outputting a first frequency signal, the oscillation circuit 51 and the multiplication circuit 52 (first group), the SAW resonator 4, the oscillation circuit 51 and the multiplication circuit 52 (second group) for outputting a second frequency signal having a frequency different from that of the first frequency signal, a switching circuit that switches between the first group and the second group, and the output circuit 53, and may be configured to be capable of selecting and outputting one of the first frequency signal and the second frequency signal from the output circuit 53 by switching between the first group and the second group using the switching circuit.

### SAW Resonator

As shown in FIGS. 8A and 8B, the SAW resonator 4 includes a package 45 and a SAW resonator element 41 which is housed in the package 45.

The package 45 includes a ceramic base material 46 having a concave portion 461 which is open to the upper surface, and a plate-like metal cover 47 which is bonded to the ceramic base material 46 so as to block an opening of the concave portion 461. In addition, the bottom of the concave portion 461 is provided with internal terminals 481 and 482 which are electrically connected to the SAW resonator element 41, and the lower surface of the ceramic base material 46 is provided with external connection terminals 483 and 484 which are electrically connected to the internal terminals 481 and 482 through a via (through-electrode) which is not shown, and external connection terminals 485 and 486 for bonding with the support substrate 3.

The SAW resonator element 41 includes a quartz crystal substrate 411 having a longitudinal shape, an IDT (Inter Digital Transducer) 412 which is provided on the upper surface of the quartz crystal substrate 411, a pair of reflectors 413 and 414 which are disposed on both sides of the IDT 412, bonding pads 415 and 416, and extraction electrodes 417 and 418 which are electrically connected to the IDT 412 and the bonding pads 415 and 416. Meanwhile, a quartz crystal resonator element using quartz crystal as a substrate material, for example, an AT cut or SC cut quartz crystal resonator element, a MEMS (Micro Electro Mechanical Systems) resonator element, or a resonator element using other substrate materials may be used instead of the SAW resonator element 41. In addition, as the substrate material of the SAW resonator element 41, the MEMS resonator element, or the resonator element, a piezoelectric material such as piezoelectric single crystal such as lithium tantalite or lithium niobate, or piezoelectric ceramics such as lead zirconate titanate, a silicon semiconductor material, or the like may be used in addition to quartz crystal. As excitation means of the SAW resonator element 41, the MEMS resonator element, or the resonator element, means based on a piezoelectric effect may be used, and electrostatic drive based on a Coulomb's force may be used.

The IDT 412 is constituted by a pair of electrodes 412a and 412b which are provided at the central portion of the quartz crystal substrate 411 in a longitudinal direction. The pair of electrodes 412a and 412b are disposed so that electrode fingers of the electrode 412a and electrode fingers of the electrode 412b are engaged with each other. When a voltage is applied between these pair of electrodes 412a and 412b, periodic distortion occurs between the electrode fingers due to the piezoelectric effect of the quartz crystal substrate 411, and a surface acoustic wave is excited in the quartz crystal substrate 411. The excited surface acoustic wave is propagated along the continuous direction of the electrode fingers.

The pair of reflectors 413 and 414 are disposed on both sides of the IDT 412 in the longitudinal direction of the quartz crystal substrate 411 with the IDT 412 interposed therebetween. The reflectors 413 and 414 have a function of reflecting a surface acoustic wave which is excited in the IDT 412 and propagated to the quartz crystal substrate 411, toward the direction of the IDT 412.

The IDT 412 and the reflectors 413 and 414 described above are formed, as a whole, so as to be shifted to one end side of the quartz crystal substrate 411 in the longitudinal direction, and a pair of bonding pads 415 and 416 are disposed on the upper surface of the quartz crystal substrate 411 on the other end side. In addition, the bonding pad 415 and the electrode 412a are electrically connected to each other through the extraction electrode 417, and the bonding pad 416 and the electrode 412b are electrically connected to each other through the extraction electrode 418.

Such a SAW resonator element 41 is disposed on the ceramic base material 46 through a bonding member. In addition, the bonding pads 415 and 416 are electrically connected to the internal terminals 481 and 482 through a bonding wire.

Such a SAW resonator 4 easily corresponds to a high frequency (frequency having, for example, a band of GHz), for example, as compared to an AT cut quartz crystal resonator. Therefore, the use of the SAW resonator 4 leads to the electronic device 1 appropriate to a high-frequency output. Specifically, since the frequency of the AT cut quartz crystal resonator depends on the thickness of the quartz crystal substrate, the quartz crystal substrate becomes thinner as the frequency becomes higher, and thus is likely to be processed. On the other hand, since the frequency of the SAW resonator depends on the interval between the electrode fingers of the IDT rather than the thickness of the quartz crystal substrate, the interval between the electrode fingers becomes shorter as the frequency becomes higher, but making the interval between the electrode fingers shorter can be easily performed by existing patterning techniques. From such reasons, the use of the SAW resonator leads to the electronic device 1 appropriate to a high frequency.

Such a SAW resonator 4 is connected to the support substrate 3 by a conductive bonding member such as solder, a conductive adhesive, silver solder, or gold solder, and is electrically connected to the oscillation circuit 51 through the conductive bonding member. Meanwhile, the SAW resonator 4 is not particularly limited to the arrangement thereof, but is preferably disposed so as to overlap the end side of the support substrate 3 in the long-axis direction as shown in FIG. 6. The end side herein refers to the lateral side 3c rather than a line segment linking the solders H1 and H4. Since such a portion serves as a free end which is not fixed to the base material 21, stress which is generated due to thermal expansion is smaller than another portion (central portion). Therefore, the SAW resonator 4 is disposed so as to overlap such a portion, whereby stress is not likely to be applied to the SAW resonator 4, and thus further stabilized drive can be performed.

As stated above, the configuration of the electronic device 1 has been described in detail. In the electronic device 1 having such a configuration, since the support substrate 3 functions as a reinforcement member that reinforces the mechanical strength of the base material 21, it is possible to increase the mechanical strength of the electronic device 1. In addition, as described above, a region except for both ends of the lateral side 3a of the support substrate 3 and a region except for both ends of the lateral side 3b thereof are bonded to the upper surface along the lateral side 21a of the base material 21 and the upper surface along the lateral side 21b thereof through the solders H1 to H6. Therefore, both ends of the support substrate 3 in the long-axis direction are unrestrained with respect to the base material 21, and the thermal expansion of the portion can be allowed. Thereby, stress caused by the thermal expansion of the portion is not likely to be generated. It is possible to reduce stress which is generated due to a thermal expansion difference between the base material 21 and the support substrate 3 to that extent, and to reduce damage of the base material 21 and the support substrate 3, the generation of cracks in the solders H1 to H6, or the like which is caused by the stress. From the above, the electronic device 1 having high reliability is obtained.

Further, in the electronic device 1, the lid 27 is fixed to the lateral sides 21c and 21d of the base material 21. Therefore, the electronic device 1 has a structure in which the bending of the base material 21 in the long-axis direction and the short-axis direction is suppressed by the support substrate 3, and the bending of the base material 21 in the long-axis direction is suppressed by the lid 27. Thereby, the bending of the base material 21 is further reduced, and thus it is possible to further increase the mechanical strength of the base material 21.

In addition, as shown in FIGS. 3A, 3B and 6, when seen in plan view, a maximum value (maximum separation distance) L1 of distances between the notched portions 311 to 316 (connection places of the support substrate 3 with the base material 21) and a center O of the base material 21 is smaller than a maximum value (maximum separation distance) L2 of distances between portions contacting the lateral sides 21a and 21b (outer edges of the lower surface) of the external connection terminals 251 to 256 and the center O of the base material 21. In addition, a second region having a rectangular shape that comes into external contact with the notched portions 311, 313, 314, and 316 is contained inside a first region having a rectangular shape that comes into external contact with the external connection terminals 251, 253, 254, and 256. Thereby, since the solders H1 to H6 that bond the base material 21 to the support substrate 3 can be disposed closer to the center O, it is possible to further reduce stress which is generated due to the thermal expansion difference between the base material 21 and the support substrate 3. Therefore, it is possible to more effectively reduce damage of the base material 21 and the support substrate 3, the generation of cracks in the solders H1 to H6, and the like.

### Second Embodiment

Next, an electronic device according to a second embodiment of the invention will be described.

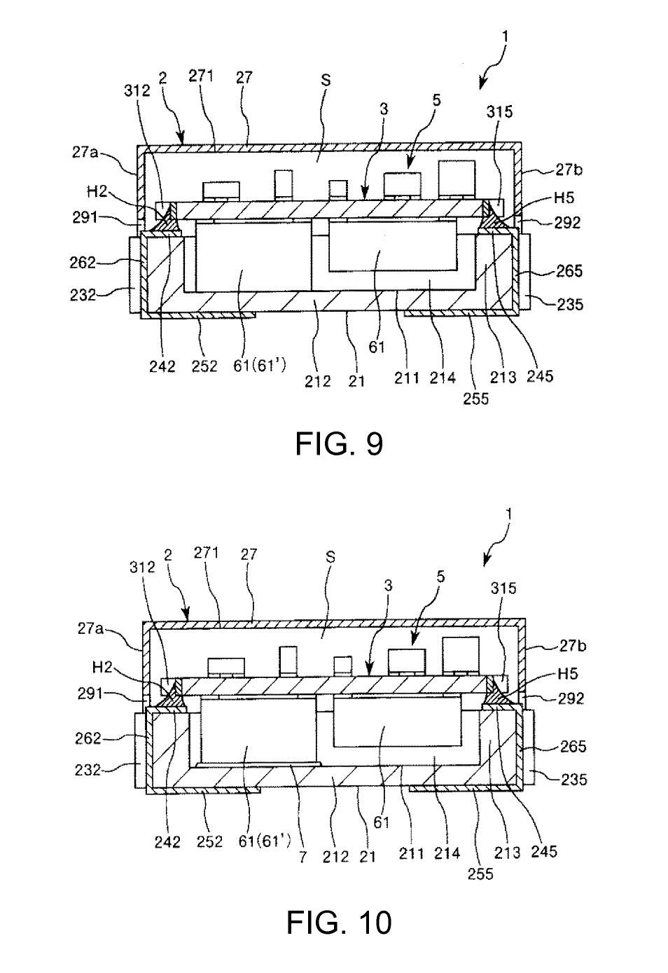

FIG. 9 is a cross-sectional view illustrating the electronic device according to the second embodiment of the invention.

Hereinafter, the electronic device according to the second embodiment of the invention will be described, but a description will be given with focus on differences from the aforementioned embodiment, and common particulars will not be described below.

The electronic device of the second embodiment is the same as that of the aforementioned first embodiment, except that at least one of the SAW resonator and the circuit element comes into contact with the base material. Meanwhile, the same components as those of the aforementioned embodiment are denoted by the same reference numerals and signs.

As shown in FIG. 9, in the electronic device 1 of the present embodiment, at least one electronic part 61′ of a plurality of electronic parts (second electronic parts) 61 comes into contact with the bottom plate 212 of the base material 21 which is provided on the lower surface of the support substrate 3. Therefore, the electronic part 61′ serves as a reinforcement member and thus the bending of the bottom plate 212 is reduced, which leads to the electronic device 1 having a higher mechanical strength.

Meanwhile, the electronic part 61′ is the SAW resonator 4 or the circuit element 59. Thereby, the SAW resonator 4 or the circuit element 59 can be effectively used as a reinforcement member. Among these electronic parts, the SAW resonator 4 or the IC chip 596 tends to be thicker than other circuit elements 59. Therefore, when these parts are provided on the lower surface of the support substrate 3, it is preferable to use these parts as the electronic part 61′. That is, it is preferable to bring the thickest of the electronic parts 61 which are provided on the lower surface of the support substrate 3 into contact with the upper surface of the bottom plate 212. If not, in order to avoid contact with the thickest part, for example, a run-off portion is required to be formed in the bottom plate 212. For this reason, there may be a concern of the complication of the shape of the bottom plate 212 or an increase in the thickness of the bottom plate 212.

In the second embodiment described above, it is also possible to exhibit the same effect as that of the aforementioned first embodiment.

### Third Embodiment

Next, an electronic device according to a third embodiment of the invention will be described.

FIG. 10 is a cross-sectional view illustrating the electronic device according to the third embodiment of the invention.

Hereinafter, the electronic device according to the third embodiment of the invention will be described, a description will be given with focus on differences from the aforementioned embodiment, and common particulars will not be described below.

The electronic device of the third embodiment is the same as that of the aforementioned first embodiment, except that at least one of the SAW resonator and the circuit element is connected to the base material through a connecting member. Meanwhile, the same components as those of the aforementioned embodiment are denoted by the same reference numerals and signs.

As shown in FIG. 10, in the electronic device 1 of the present embodiment, at least one electronic part 61′ of a plurality of electronic parts (second electronic parts) 61 which are provided on the lower surface of the support substrate 3 is connected to the bottom plate 212 of the base material 21 through a connecting member 7. Therefore, the electronic part 61′ serves as a reinforcement member and thus the bending of the bottom plate 212 is reduced, which leads to the electronic device 1 having a higher mechanical strength.

The connecting member 7 may or may not have an adhesive property. That is, the electronic part 61′ may be bonded to the bottom plate 212 through the connecting member 7, and may just come into contact with the bottom plate through the connecting member 7. When the connecting member 7 has an adhesive property, the electronic part 61′ and the bottom plate 212 can be bonded to each other, whereby the mechanical strength of the base material 21 can be further increased, but the connecting member 7 has to be cured, which results in the possibility of an increase in the number of processes of manufacturing the electronic device 1. On the other hand, when the connecting member 7 does not have an adhesive property, there is the possibility of a further decrease in the effect of increasing the mechanical strength of the base material 21 than in a case where the connecting member has an adhesive property, but the number of processes of manufacturing the electronic device 1 is reduced by the number of curing processes.

In addition, the connecting member 7 preferably has relatively high thermal conductivity. Thereby, it is possible to transfer the heat of the electronic part 61′ to the base material 21 through the connecting member 7, and to exhibit an excellent heat radiation effect. From the viewpoint of heat radiation, as for the electronic part 61′, the component having a higher calorific value in the SAW resonator 4 and the circuit element 59 is preferable, and specifically, the SAW resonator 4 or the IC chip 596 is preferable. Thereby, the electronic device 1 having a more excellent heat radiation effect is obtained. In addition, as described in the aforementioned second embodiment, it is effective in that these components tend to be thicker than other circuit elements 59.

Such a connecting member 7 is not particularly limited. For example, a metal brazing material such as silicone oil (silicone grease), solder, gold solder, or silver solder, a material obtained by dispersing a thermal conductive filler (such as metal powder, graphite, carbon black, aluminum nitride, boron nitride, or alumina) in a resin, or the like can be used as the connecting member.

In the third embodiment described above, it is also possible to exhibit the same effect as that of the aforementioned first embodiment.

### Fourth Embodiment

Next, an electronic device according to a fourth embodiment of the invention will be described.

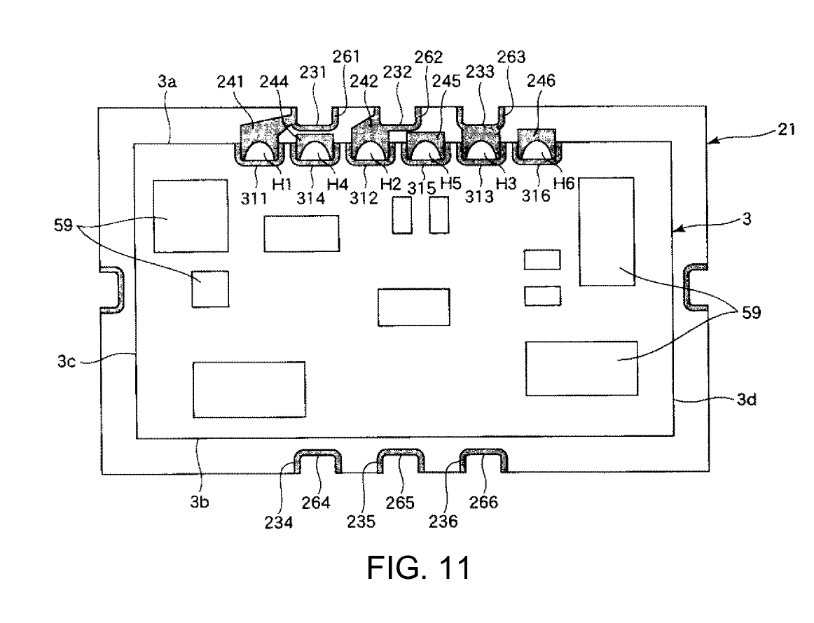

FIG. 11 is a plan view illustrating the electronic device according to the fourth embodiment of the invention.

Hereinafter, the electronic device according to the Fourth embodiment of the invention will be described, but a description will be given with focus on differences from the aforementioned embodiment, and common particulars will not be described below.

The electronic device of the fourth embodiment is the same as that of the aforementioned first embodiment, except that the fixed places of the support substrate 3 are different from the above ones. Meanwhile, the same components as those of the aforementioned embodiment are denoted by the same reference numerals and signs.

As shown in FIG. 11, in the electronic device 1 of the present embodiment, six notched portions 311 to 316 are provided on the lateral side 3a of the support substrate 3. These notched portions 311 to 316 are disposed near the central portion so as to keep away from both ends of the lateral side 3a. The support substrate 3 having such a configuration is fixed to the base material 21 through the solders H1 to H6 at the lateral side 3a.

In the fourth embodiment described above, it is also possible to exhibit the same effect as that of the aforementioned first embodiment.

### Fifth Embodiment

Next, an electronic device according to a fifth embodiment of the invention will be described.

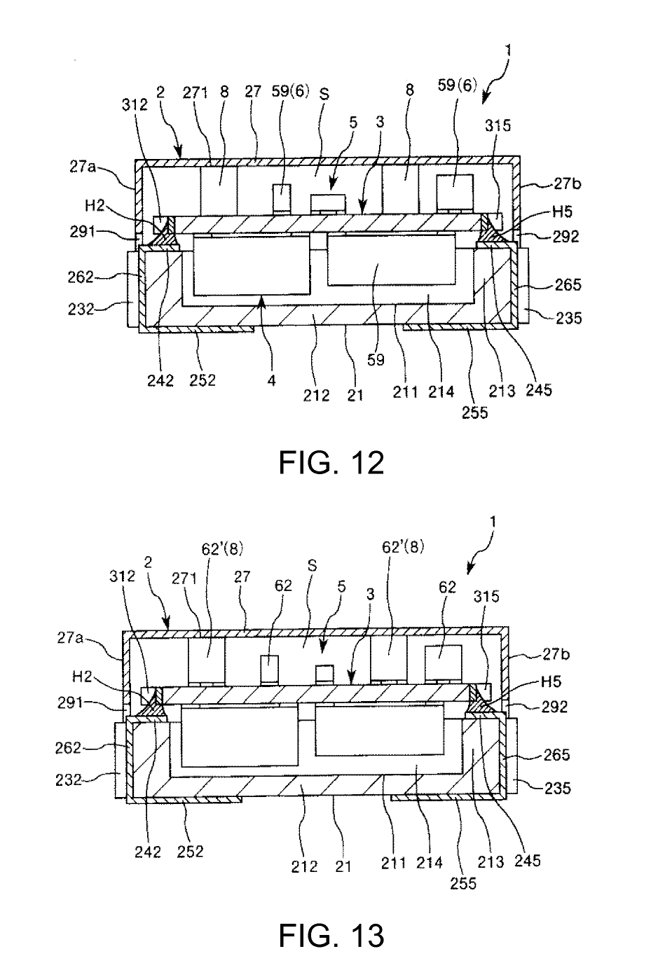

FIG. 12 is a cross-sectional view illustrating the electronic device according to the fifth embodiment of the invention.

Hereinafter, the electronic device according to the fifth embodiment of the invention will be described, but a description will be given with focus on differences from the aforementioned embodiment, and common particulars will not be described below.

The electronic device of the second embodiment is the same as that of the aforementioned first embodiment, except that a strut is included. Meanwhile, the same components as those of the aforementioned embodiment are denoted by the same reference numerals and signs.

As shown in FIG. 12, the electronic device 1 of the present embodiment includes a strut (columnar member) 8 which is provided on the upper surface of the support substrate 3 so as to protrude upward from the support substrate 3. This strut 8 is located between the support substrate 3 and the lid 27 (bottom of the concave portion 271), and is configured such that the upper end thereof comes into contact with the lid 27. Therefore, the strut 8 serves as a reinforcement member and thus the bending of the lid 27 is reduced, which leads to the electronic device 1 having a higher mechanical strength. In addition, the strut 8 is formed higher than any of the electronic parts 6 which are provided on the upper surface of the support substrate 3, thereby allowing the electronic parts 6 and the lid 27 to be prevented from coming into contact with each other. Here, the electronic part 6 is the SAW resonator 4 or the circuit element 59, but these electronic parts may have an electrode on the upper surface (position facing the lid 27) (for example, chip coil, transistor, capacitor, or the like). When the lid 27 is bent and comes into contact with such an electronic part 6, there may be a concern of a short circuit being generated. Therefore, the bending of the lid 27 is reduced by the strut 8, and the electronic parts 6 and the lid 27 are prevented from coming into contact with each other, which leads to the electronic device 1 having high reliability.

Meanwhile, the strut 8 may be formed integrally with the support substrate 3, and may be formed separately from the support substrate 3 and be connected to the upper surface of the support substrate 3 by a bonding member or the like. In addition, the strut 8 may be bonded to the lid 27, through, for example, the bonding member or the like. In addition, on the contrary to the present embodiment, the strut 8 may be provided on the bottom of the concave portion 271 of the lid 27 so as to protrude downward from the lid 27, and may be configured such that the lower end thereof comes into contact with the upper surface of the support substrate 3.

In the fifth embodiment described above, it is also possible to exhibit the same effect as that of the aforementioned first embodiment.

### Sixth Embodiment

Next, an electronic device according to a sixth embodiment of the invention will be described.

FIG. 13 is a cross-sectional view illustrating the electronic device according to the sixth embodiment of the invention.

Hereinafter, the electronic device according to the sixth embodiment of the invention will be described, but a description will be given with focus on differences from the aforementioned embodiment, and common particulars will not be described below.

The electronic device of the sixth embodiment is the same as that of the aforementioned fifth embodiment, except that the electronic parts serve as the strut. Meanwhile, the same components as those of the aforementioned embodiment are denoted by the same reference numerals and signs.

As shown in FIG. 13, in the electronic device 1 of the present embodiment, at least one electronic part 62′ of a plurality of electronic parts (first electronic parts) 62 which are provided on the upper surface of the support substrate 3 comes into contact with the lid 27 (bottom of the concave portion 271). That is, the electronic part 62′ serves as the strut 8. Therefore, the electronic part 62′ serves as a reinforcement member and thus the bending of the lid 27 is reduced, which leads to the electronic device 1 having a higher mechanical strength. In addition, since the strut 8 is not required to be separately provided, it is possible to achieve a reduction in the size the electronic device 1 to that extent. Meanwhile, the electronic part 62′ is the SAW resonator 4 or the circuit element 59. Thereby, it is possible to effectively use the SAW resonator 4 or the circuit element 59 as a reinforcement member. Among these electronic parts, as for the electronic part 62′, it is preferable that an electrical obstacle such as a short circuit is not be able to be generated even due to the contact with the lid 27. That is, it is preferable that an electrode does not face a location which is capable of coming into contact with the lid 27.

In the sixth embodiment described above, it is also possible to exhibit the same effect as that of the aforementioned first embodiment.

### Seventh Embodiment

Next, an electronic device according to a seventh embodiment of the invention will be described.

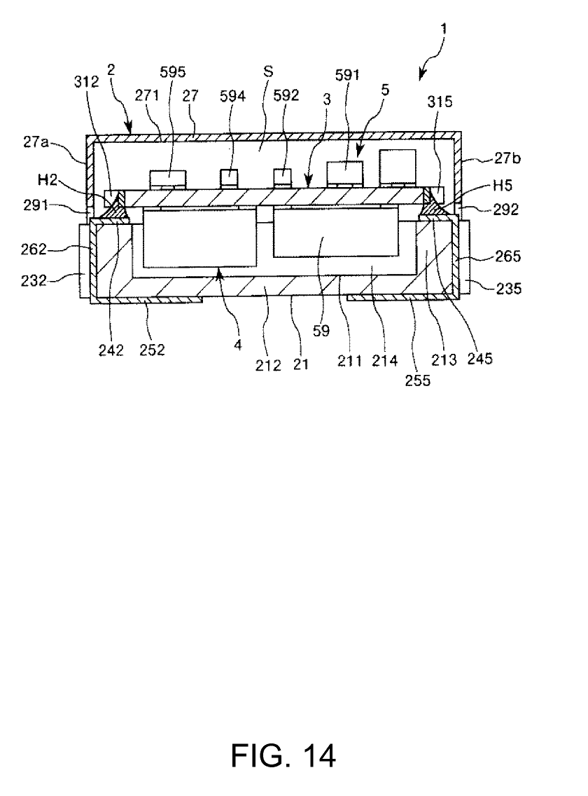

FIG. 14 is a cross-sectional view illustrating the electronic device according to the seventh embodiment of the invention.

Hereinafter, the electronic device according to the seventh embodiment of the invention will be described, but a description will be given with focus on differences from the aforementioned embodiment, and common particulars will not be described below.

The electronic device of the seventh embodiment is the same as that of the aforementioned first embodiment, except that the arrangement of the circuit elements is different from the above. Meanwhile, the same components as those of the aforementioned embodiment are denoted by the same reference numerals and signs.

As shown in FIG. 14, in the electronic device 1 of the present embodiment, at least the chip coil 591 and the chip capacitor 592 included in the oscillation circuit 51 and the chip coil 594 and the chip capacitor 595 included in the multiplication circuit 52 are disposed on the upper surface of the support substrate 3. As described in the aforementioned first embodiment, it is possible to adjust the output frequency f1 from the oscillation circuit 51 by exchanging the chip coil 591 or the chip capacitor 592 for an element having different inductance or capacitance, and to adjust the bandpass of the bandpass filter by exchanging the chip coil 594 or the chip capacitor 595 for an element having different inductance or capacitance. In this manner, the circuit element 59 capable of being exchanged in order to adjust the characteristics of the circuit 5 is disposed on the upper surface of the support substrate 3, thereby allowing the exchange to be simply performed. Specifically, the adjustment of the circuit 5 is performed before the lid 27 is covered, and the upper surface of the support substrate 3 is exposed to the outside in this state. Therefore, it is possible to easily perform the exchange of the circuit element 59 which is disposed on the upper surface of the support substrate 3. In this manner, according to the present embodiment, it is possible to obtain the electronic device 1 which is capable of easily adjusting the characteristics of the circuit 5.

In the sixth embodiment described above, it is also possible to exhibit the same effect as that of the aforementioned first embodiment.

Meanwhile, in the present embodiment, the chip coil 591, the chip capacitor 592, the chip coil 594 and the chip capacitor 595 are provided on the upper surface of the support substrate 3. When at least one of these elements is provided on the upper surface of the support substrate 3, the others may be provided on the lower surface of the support substrate 3.

### 2. Electronic Apparatus

Next, an electronic apparatus including the electronic device 1 will be described.

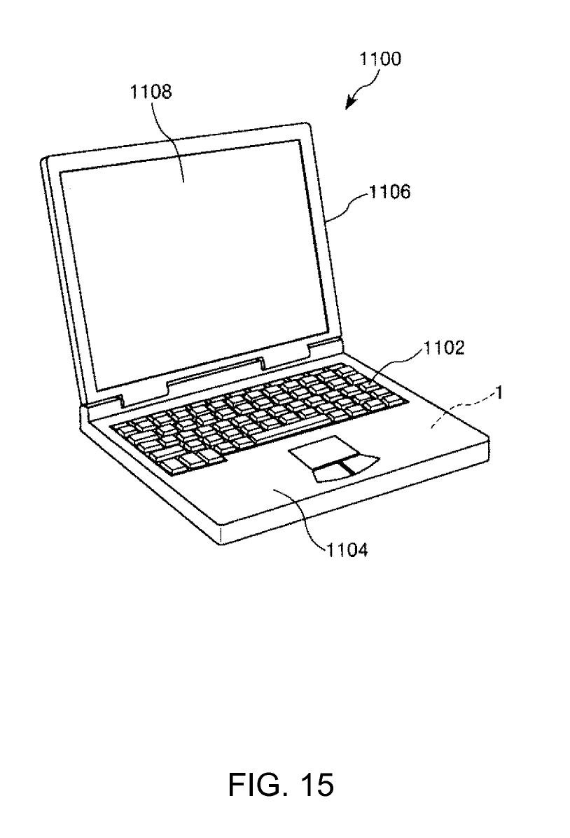

FIG. 15 is a perspective view illustrating a configuration of a mobile-type (or note-type) personal computer to which the electronic apparatus according to the invention is applied. In this drawing, a personal computer 1100 is constituted by a main body 1104 including a keyboard 1102 and a display unit 1106 including a display portion 1108, and the display unit 1106 is rotatably supported with respect to the main body 1104 through a hinge structure. Such a personal computer 1100 has the built-in electronic device 1 functioning as a filter, a resonator, a reference clock, or the like.

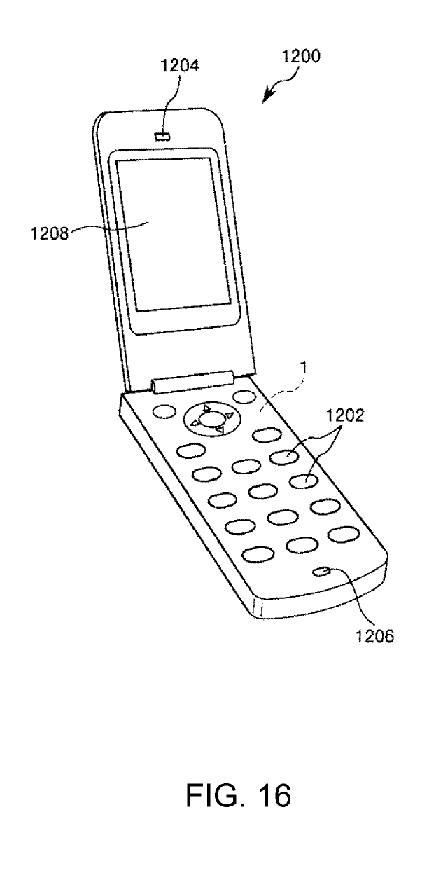

FIG. 16 is a perspective view illustrating a configuration of a cellular phone (also including PHS) to which the electronic apparatus according to the invention is applied. In this drawing, a cellular phone 1200 includes a plurality of operation buttons 1202, an ear piece 1204 and a mouth piece 1206, and a display portion 1208 is disposed between the operation buttons 1202 and the ear piece 1204. Such as cellular phone 1200 has the built-in electronic device 1 functioning as a filter, a resonator, a reference clock, or the like.

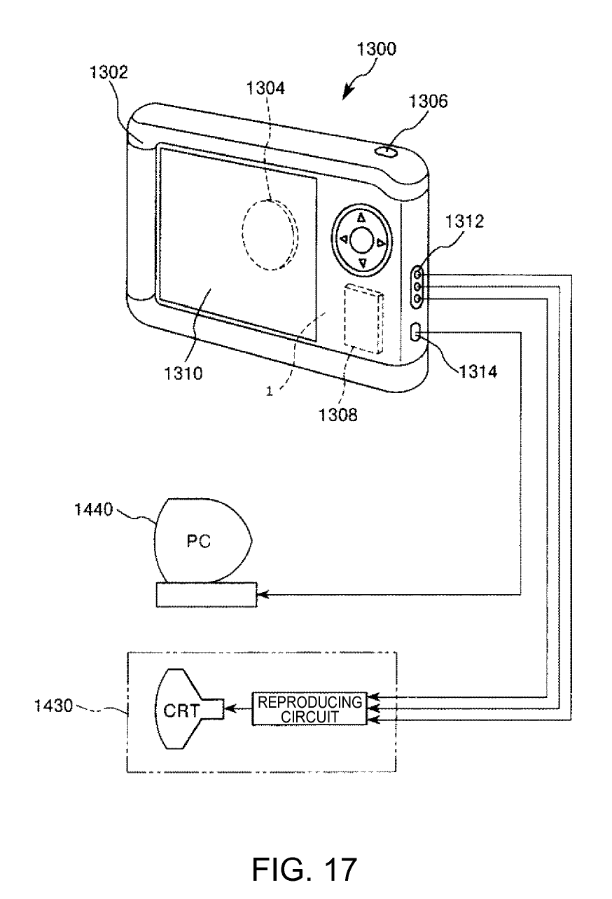

FIG. 17 is a perspective view illustrating a configuration of a digital still camera to which the electronic apparatus according to the invention is applied. Meanwhile, in the drawing, the connection with an external device is also shown simply. Here, a normal camera exposes a silver halide photo film through a light image of a subject, whereas a digital still camera 1300 generates an imaging signal (image signal) by photoelectrically converting a light image of a subject using an imaging device such as a CCD (Charge Coupled Device).

A display portion 1310 is provided on the rear of a case (body) 1302 in the digital still camera 1300, and is configured to perform a display on the basis of an imaging signal of a CCD. The display portion functions as a viewfinder for displaying a subject as an electronic image. In addition, a light-receiving unit 1304 including an optical lens (imaging optical system), a CCD and the like is provided on the front side (back side in the drawing) of the case 1302.

When a photographer confirms a subject image displayed on the display portion and pushes a shutter button 1306, an imaging signal of the CCD at that point in time is transmitted and stored to and in a memory 1308. In addition, in the digital still camera 1300, a video signal output terminal 1312 and an input and output terminal 1314 for data communication are provided on the lateral side of the case 1302. As shown in the drawing, a TV monitor 1430 is connected to the video signal output terminal 1312, and a personal computer 1440 is connected to the input and output terminal 1314 for data communication, respectively as necessary. Further, the imaging signal stored in the memory 1308 is output to the TV monitor 1430 or the personal computer 1440 by a predetermined operation. Such a digital still camera 1300 has the built-in electronic device 1 functioning as a filter, a resonator, a reference clock, or the like.

Meanwhile, in addition to the personal computer (mobile-type personal computer) of FIG. 15, the cellular phone of FIG. 16, and the digital still camera of FIG. 17, the electronic apparatus including the electronic device can be applied to, for example, a mobile terminal such as a smartphone, a communication device, an ink jet ejecting apparatus (for example, ink jet printer), a laptop personal computer, a tablet personal computer, a storage area network device such as a router or a switch, a local area network device, a device for a mobile terminal and a base station, a television, a video camera, a video recorder, a car navigation device, a real-time clock device, a pager, an electronic notebook (including one with a communication function), an electronic dictionary, an electronic calculator, an electronic game console, a word processor, a workstation, a TV phone, a security TV monitor, electronic binoculars, a POS terminal, a medical instrument (for example, an electronic thermometer, a sphygmomanometer, a blood glucose monitoring system, an electrocardiogram measurement device, an ultrasound diagnostic device, or an electronic endoscope), a fish finder, various types of measuring apparatuses, meters and gauges (for example, meters and gauges of a vehicle, an airplane, or a vessel), a flight simulator, a head mounted display, a motion tracer, a motion tracker, a motion controller, PDR (walker position and direction measurement), and the like.

### 3. Moving Object

Next, a moving object including the electronic device 1 will be described.

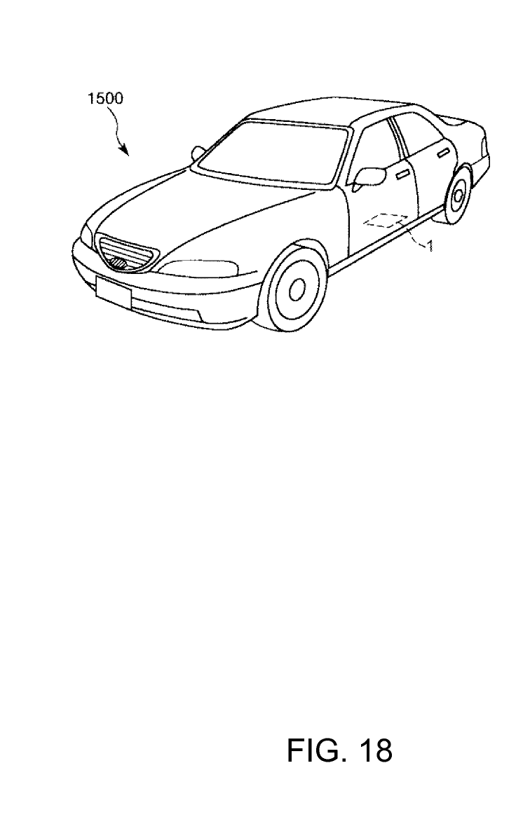

FIG. 18 is a perspective view illustrating an automobile to which the moving object is applied. The electronic device 1 is mounted to an automobile 1500. The electronic device 1 can be applied widely to, for example, electronic control units (ECUs) such as a keyless entry, an immobilizer, a car navigation system, a car air conditioner, an antilock brake system (ABS), an air bag, a tire pressure monitoring system (TPMS), an engine controller, a braking system, a battery monitor of a hybrid automobile or an electric automobile, and a car-body posture control system.

As described above, the electronic device, the electronic apparatus and the moving object according to the invention have been described on the basis of the shown embodiments, but the invention is not limited thereto, and the configuration of each portion can be replaced by any configuration having the same function. In addition, any other configurations may be added to the invention. In addition, the invention may be configured such that any two or more configurations in the above embodiments may be combined.

In addition, in the aforementioned embodiment, a configuration has been described in which the SAW resonator element is used as the resonator element, but the resonator element is not limited thereto. For example, as the resonator element, an AT cut quartz crystal resonator (thickness-shear mode resonator) element may be used, and a tuning fork-type resonator (flexural resonator) element may be used. In addition, in the aforementioned embodiment, a configuration has been described in which the electronic device is applied to the voltage controlled SAW oscillator (VCSO), but in addition to this, the electronic device can be applied to an oscillator such as a SAW oscillator (SPSO), a crystal oscillator (SPXO), a voltage-controlled crystal oscillator (VCXO), a temperature-compensated crystal oscillator (TCXO), an oven-controlled crystal oscillator (OCXO), or a MEMS oscillator, an inertial sensor such as an acceleration sensor and a gyro sensor, and a physical quantity sensor such as a force sensor of an inclination sensor.

The entire disclosure of Japanese Patent Application No. 2014-046979, filed Mar. 10, 2014 is expressly incorporated by reference herein.

What is claimed is:

1. An electronic device comprising:
a base material in which a concave portion is provided; and
a substrate that includes a lateral side to which a first main surface and a second main surface, being in a front-back relationship with each other, are connected, the lateral side including a first lateral side and a second lateral side which are disposed so as to face each other, and a third lateral side and a fourth lateral side, disposed so as to face each other, which intersect the first lateral side and the second lateral side,
wherein the substrate overlaps an opening region of the concave portion when seen in plan view, and the second main surface faces the inner bottom of the concave portion, and
at least any one of at least a portion of a region between both ends of the first lateral side in a direction in which the third lateral side and the fourth lateral side are linked, and at least a portion of a region between both ends of the second lateral side in the linking direction is bonded to a sidewall of the concave portion through a connecting member.

2. The electronic device according to claim 1, wherein the substrate is formed of ceramic.

3. The electronic device according to claim 1, wherein an external connection terminal is provided on a surface of the concave portion on an opposite side to the inner bottom, and
when seen in plan view, a maximum value of a distance between a connection place of the substrate with the base material and a center of the base material is smaller than a maximum value of a distance between a portion of the external connection terminal contacting an outer edge of the surface on the opposite side and the center of the base material.

4. The electronic device according to claim 1, further comprising a lid which is bonded to the base material so as to cover the substrate,
wherein the lid is bonded to a portion of the sidewall located along the third lateral side and a portion of the sidewall located along the fourth lateral side.

5. The electronic device according to claim 3, further comprising a lid which is bonded to the base material so as to cover the substrate,
wherein the lid is bonded to a portion of the sidewall located along the third lateral side and a portion of the sidewall located along the fourth lateral side.

6. The electronic device according to claim 4, wherein a columnar member is provided between the first main surface and the lid, and the columnar member comes into contact with the substrate and the lid.

7. The electronic device according to claim 6, further comprising a first electronic part, provided on the first main surface, which serves as the columnar member.

8. The electronic device according to claim 7, wherein a resonator and a circuit which is connected to the resonator are provided on the substrate, and
the first electronic part is a circuit element included in the resonator or the circuit.

9. The electronic device according to claim 1, further comprising a second electronic part, provided on the second main surface, which comes into contact with the bottom plate.

10. The electronic device according to claim 1, further comprising a second electronic part, provided on the second main surface, which is connected to the bottom plate through a connecting member.

11. The electronic device according to claim 9, wherein a resonator and a circuit which is connected to the resonator are provided on the substrate, and
wherein the second electronic part is a circuit element included in the resonator or the circuit.

12. An electronic apparatus comprising the electronic device according to claim 1.

13. An electronic apparatus comprising the electronic device according to claim 3.

14. An electronic apparatus comprising the electronic device according to claim 4.

15. An moving object comprising the electronic device according to claim 1.

16. An moving object comprising the electronic device according to claim 3.

17. An moving object comprising the electronic device according to claim 4.
